(19) United States
(12) Patent Application Publication
(10) Pub. No.: US 2024/0360590 A1
(43) Pub. Date: Oct. 31, 2024

(54) GAS EXHAUST FRAMES INCLUDING PATHWAYS HAVING SIZE VARIATIONS, AND RELATED APPARATUS AND METHODS

(71) Applicant: Applied Materials, Inc., Santa Clara, CA (US)

(72) Inventors: Vishwas Kumar PANDEY, Madhya Pradesh (IN); Ala MORADIAN, Sunnyvale, CA (US); Lori WASHINGTON, San Jose, CA (US)

(21) Appl. No.: 18/140,508

(22) Filed: Apr. 27, 2023

(51) Int. Cl. C30B 25/14; C23C 16/44; C23C 16/458; C30B 25/10; C30B 25/12

(52) U.S. Cl. CPC C30B 25/14; C23C 16/4412; C23C 16/4583; C30B 25/10; C30B 25/12

(57) ABSTRACT

Embodiments of the present disclosure relate to gas exhaust frames including pathways having size variations, for use in a substrate processing chamber, and related apparatus and methods. In one or more embodiments, a processing chamber includes a chamber body, and a window. The processing chamber includes one or more heat sources, a substrate support, a liner, and a pre-heat ring. The processing chamber includes one or more gas inlets, and a first set of exhaust pathways positioned on a first side of a reference plane. The first set of exhaust pathways have a first cross-sectional area gradient that increases along a first direction. The processing chamber includes a second set of exhaust pathways positioned on a second side of the reference plane. The second set of exhaust pathways have a second cross-sectional area gradient that increases along a second direction that is opposite of the first direction.

### BACKGROUND

### Field

Embodiments of the present disclosure relate to gas exhaust frames including pathways having size variations, for use in a substrate processing chamber, and related apparatus and methods.

### Description of the Related Art

Continuous reduction in size of semiconductor devices is dependent upon more precise control of, for instance, the flow and temperature of process gases delivered to a semiconductor process chamber. Oftentimes, in a cross-flow chamber, a process gas may be delivered to the chamber and directed across the surface of a substrate to be processed. The deposition uniformity on the substrate may be affected by, for example, gas flow rates.

For example, the non-uniformity in gas flow rates can involve a plume-shaped profile of gas concentrations. Additionally, modularity of adjusting process parameters can be limited, which can hinder deposition uniformity (such as center-to-edge uniformity).

Therefore, a need exists for improved processing chambers that facilitate deposition uniformity, and methods of using the same.

### SUMMARY

Embodiments of the present disclosure relate to gas exhaust frames including pathways having size variations, for use in a substrate processing chamber, and related apparatus and methods.

In one or more embodiments, a processing chamber applicable for use in semiconductor manufacturing includes a chamber body, and a window, the chamber body and the window at least partially defining a processing volume. The processing chamber includes one or more heat sources configured to heat the processing volume, a substrate support disposed in the processing volume, a liner at least partially lining the chamber body, and a pre-heat ring disposed in the processing volume and at least partially supported by the liner. The processing chamber includes one or more gas inlets, and a first set of exhaust pathways positioned opposite of the one or more gas inlets on a first side of a reference plane. The first set of exhaust pathways have a first cross-sectional area gradient that increases along a first direction. The processing chamber includes a second set of exhaust pathways positioned opposite of the one or more gas inlets on a second side of the reference plane. The second set of exhaust pathways have a second cross-sectional area gradient that increases along a second direction that is opposite of the first direction.

In one or more embodiments, a gas exhaust frame for insertion in a processing chamber applicable for use in semiconductor manufacturing. The gas exhaust frame includes a first outer face, a second outer face, and a third outer face. The second outer face and the third outer face extend relative to the first outer face along a length, and the gas exhaust frame has a height between the second outer face and the third outer face. The gas exhaust frame includes a plurality of exhaust pathways having a size variation such that at least part of each exhaust pathway of the plurality of exhaust pathways is different in size than each of the other exhaust pathways of the plurality of exhaust pathways.

In one or more embodiments, a method of altering a processing chamber applicable for use in semiconductor processing includes positioning a liner in a processing volume, the liner including an opening. The method includes positioning one or more gas exhaust frames at least partially in the opening of the liner. The one or more gas exhaust frames include a first set of exhaust pathways positioned on a first side of a reference plane, the first set of exhaust pathways having a first cross-sectional area gradient that increases along a first direction. The one or more gas exhaust frames include a second set of exhaust pathways positioned on a second side of the reference plane, the second set of exhaust pathways having a second cross-sectional area gradient that increases along a second direction that is opposite of the first direction. The method includes fluidly connecting the one or more exhaust frames to an exhaust assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic top view of the processing chamber shown in FIG. 1, according to one or more embodiments.

FIG. 3 is a schematic axonometric view of a pair of gas exhaust frames, according to one or more embodiments.

FIG. 4 is a schematic top view of the pair of gas exhaust frames shown in FIG. 3, according to one or more embodiments.

FIG. 5 is a schematic axonometric view of a pair of gas exhaust frames, according to one or more embodiments.

FIG. 6 is a schematic top view of the pair of gas exhaust frames shown in FIG. 5, according to one or more embodiments.

FIG. 7 is a schematic axonometric view of a pair of gas exhaust frames, according to one or more embodiments.

FIG. 8 is a schematic top view of the pair of gas exhaust frames shown in FIG. 7, according to one or more embodiments.

FIG. 9 is a schematic axonometric view of a pair of gas exhaust frames, according to one or more embodiments.

FIG. 10 is a schematic top view of the pair of gas exhaust frames shown in FIG. 9, according to one or more embodiments.

FIG. 11 is a schematic axonometric view of a pair of gas exhaust frames, according to one or more embodiments.

FIG. 12 is a schematic top view of the pair of gas exhaust frames shown in FIG. 11, according to one or more embodiments.

FIG. 13 is a schematic axonometric view of a pair of gas exhaust frames, according to one or more embodiments.

FIG. 14 is a schematic front view of the pair of gas exhaust frames shown in FIG. 13, according to one or more embodiments.

FIG. 15 is a schematic axonometric view of the pair of gas exhaust frames shown in FIGS. 13 and 14, according to one or more embodiments.

FIG. 16 is a schematic front view of the pair of gas exhaust frames shown in FIG. 15, according to one or more embodiments.

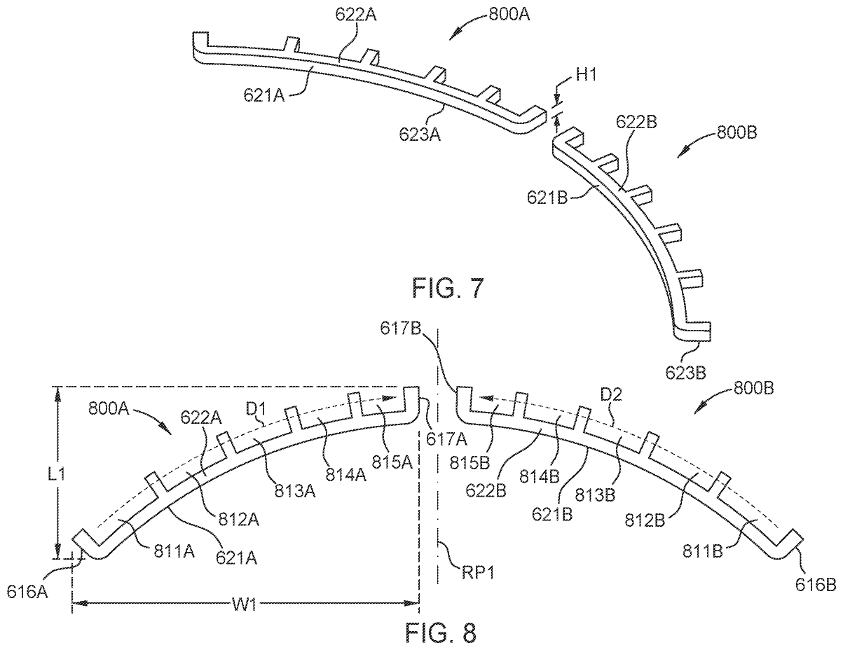

FIG. 7 is a schematic axonometric view of a pair of gas exhaust frames, according to one or more embodiments.

FIG. 18 is a schematic front view of the pair of gas exhaust frames shown in FIG. 18, according to one or more embodiments.

FIG. 19 is a schematic flow diagram of a method of altering a processing chamber applicable for use in semiconductor processing, according to one or more embodiments.

FIG. 20 is a schematic top view of a substrate during a deposition operation, according to one or more embodiments.

FIG. 21 is a schematic top view of a substrate during a deposition operation, according to one or more embodiments.

FIG. 22 is a schematic graphical view of deposition thickness versus substrate radius, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to gas exhaust frames including pathways having size variations, for use in a substrate processing chamber, and related apparatus and methods. The size variations facilitate modularity in adjusting gas parameters (such as zones of flow rate, zones of pressure, and/or zones of temperature) to facilitate enhanced deposition uniformity (such as center-to-edge uniformity).

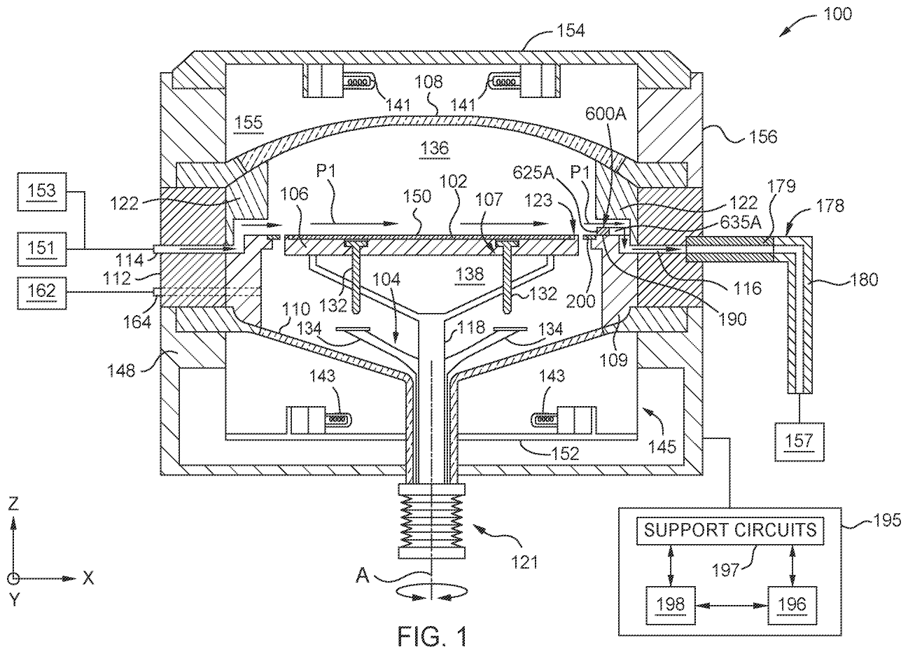

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form at least part of a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 195 is in communication with the processing chamber 100 and is used to control processes and methods, such as at least part of the operations of the methods described herein.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper lamp module 155. The lid 154 may include a plurality of sensors disposed therein or thereon for measuring the temperature within the processing chamber 100. The plurality of lower heat sources 143 are disposed between the lower window 110 and a floor 152. The plurality of lower heat sources 143 form a portion of a lower lamp module 145. The upper window 108 and the lower window 110 are formed of an energy transmissive material, such as quartz.

A process volume 136 and a purge volume 138 are formed between the upper window 108 and the lower window 110. The process volume 136 and the purge volume 138 are part of an internal volume defined at least partially by the upper window 108, the lower window 110, an upper liner 122, and a lower liner 109.

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are sized to accommodate lift pins 132 for lowering and lifting of the substrate 102 to and from the substrate support 106 before or and a deposition process is performed. The lift pins 132 may rest on lift pin stops 134 when the substrate support 106 is lowered from a process position to a transfer position. The lift pin stops 134 can be coupled to a second shaft 104 through a plurality of arms.

The flow module 112 includes one or more gas inlets 114 (a plurality is shown), a plurality of purge gas inlets 164, and one or more gas exhaust outlets 116. In one or more embodiments, the plurality of gas inlets 114 and the plurality of purge gas inlets 164 are disposed on the opposite side of the flow module 112 from the one or more gas exhaust outlets 116. The upper liner 122 and the lower liner 109 are disposed on an inner surface of the flow module 112 and protect the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂), and/or nitrogen (N₂)). One or more cleaning gases supplied using the one or more cleaning gas sources 153 can include one or more of hydrogen (H) and/or chlorine (CI). In one or more embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. In one or more embodiments, the exhaust system 178 is disposed on an opposite side of the processing chamber 100 relative to the gas inlet(s) 114 and/or the purge gas inlets 164. The exhaust system 178 includes a pair of gas boxes 179 and a common gas box 180.

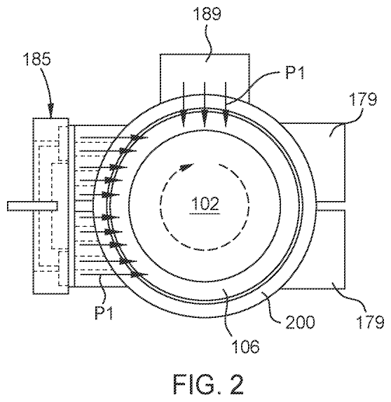

A pre-heat ring 200 is disposed outwardly of the substrate support 106. The pre-heat ring 200 is supported on a ledge of the lower liner 109. The pre-heat ring 200 is described further in FIGS. 2-10. In one or more embodiments, the pre-heat ring 200 and/or the liners 109 and/or 122 are formed of one or more of quartz (such as transparent quartz, e.g. clear quartz; opaque quartz, e.g., white or grey quartz; and/or black quartz), silicon carbide (SiC), and/or graphite coated with SiC.

One or more process gases P1 flow from the gas inlet(s) 114, into the processing volume 136, and over the substrate 102 to form (e.g., epitaxially grow) one or more layers on the substrate 102 while the heat sources 141, 143 heat the pre-heat ring 200 and the substrate 102. After flowing over the substrate 102, the one or more process gases P1 flow out of the internal volume through the one or more gas exhaust outlets 116. The flow module 112 can be at least part of a sidewall of the processing chamber 100. The present disclosure also contemplates that one or more purge gases can be supplied to the purge volume 138 (through the plurality of purge gas inlets 164) during the deposition operation, and exhausted from the purge volume 138.

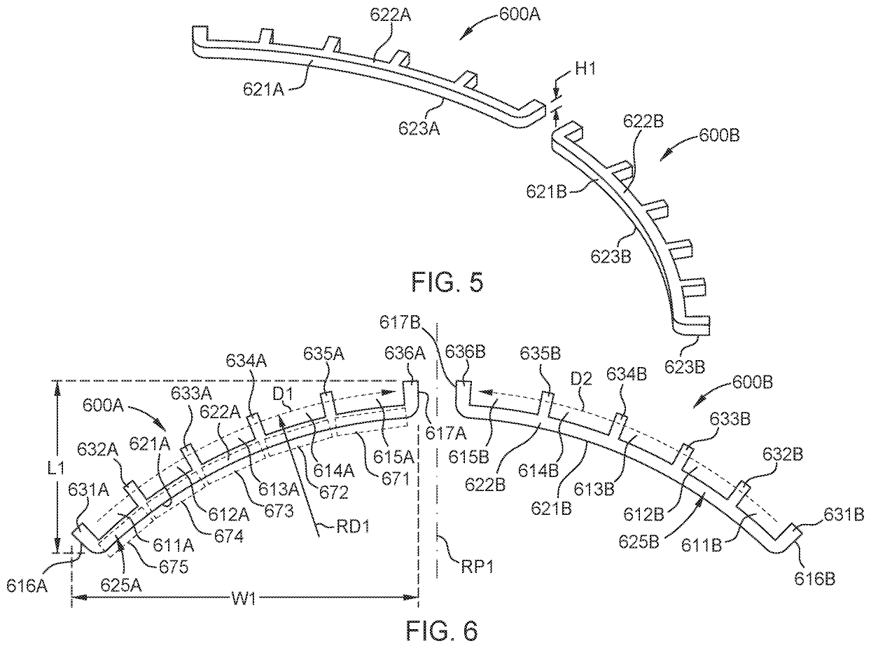

The lower liner 109 includes an opening 190 (such as an upper recess), and a pair of gas exhaust frames 600A, 600B (a first gas exhaust frame 600A is shown in FIG. 1) are positioned at least partially in the opening 190. The gas exhaust frames 600A, 600B are further described in relation to FIG. 5 below.

As shown, a controller 195 is in communication with the processing chamber 100 and is used to control processes and methods, such as at least some of the operations of the methods described herein.

The controller 195 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 100 (such as inner surfaces of the upper window 108 and/or the liners 109, 122); sensors that monitor gas flow of the one or more process gases P1; and/or sensors that monitor temperatures of the substrate 102, the substrate support 106, the upper window 108, and/or the liners 109, 122. The controller 195 is equipped with or in communication with a system model of the processing chamber 100. The system model includes a heating model, a deposition model, a coating model, a rotational position model, and/or a gas flow model. The system model is a program configured to estimate parameters (such as a gas flow rate, a center-to-edge uniformity profile, a gas pressure, a processing temperature, a rotational position of component(s), a heating profile, a coating condition, and/or a cleaning condition) within the processing chamber 100 throughout a deposition operation and/or a cleaning operation. The controller 195 is further configured to store readings and calculations. The readings and calculations include previous sensor readings, such as any previous sensor readings within the processing chamber 100. The readings and calculations further include the stored calculated values from after the sensor readings are measured by the controller 195 and run through the system model. Therefore, the controller 195 is configured to both retrieve stored readings and calculations as well as save readings and calculations for future use. Maintaining previous readings and calculations enables the controller 195 to adjust the system model over time to reflect a more accurate version of the processing chamber 100.

The controller 195 can monitor, estimate an optimized parameter, adjust a size of a cross-sectional area of an exhaust pathway of the gas exhaust frames 600A, 600B, detect a coating condition for the upper window 108, generate an alert on a display, halt a deposition operation, initiate a chamber downtime period, delay a subsequent iteration of the deposition operation, initiate a cleaning operation, detect a cleaning condition for the upper window 108, halt the cleaning operation, adjust a heating power, and/or otherwise adjust the process recipe.

The controller 195 includes a central processing unit (CPU) 198 (e.g., a processor), a memory 196 containing instructions, and support circuits 197 for the CPU 198. The controller 195 controls various items directly, or via other computers and/or controllers. In one or more embodiments, the controller 195 is communicatively coupled to dedicated controllers, and the controller 195 functions as a central controller.

The controller 195 is of any form of a general-purpose computer processor that is used in an industrial setting for controlling various substrate processing chambers and equipment, and sub-processors thereon or therein. The memory 196, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 197 of the controller 195 are coupled to the CPU 198 for supporting the CPU 198. The support circuits 197 include cache, power supplies, clock circuits, input/output circuitry and subsystems, and the like. Operational parameters (e.g., a center-to-edge profile, the coating condition, a pressure for process gases P1, a processing temperature, a heating profile, a flow rate for process gases P1, a pressure for cleaning gases, a flow rate for cleaning gases, and/or a rotational position of the substrate support 106) and operations are stored in the memory 196 as a software routine that is executed or invoked to turn the controller 195 into a specific purpose controller to control the operations of the various chambers/modules described herein. The controller 195 is configured to conduct any of the operations described herein. The instructions stored on the memory, when executed, cause one or more of operations of method 2000 (described below) to be conducted in relation to the processing chamber 100. The controller 195 and the processing chamber 100 are at least part of a system for processing substrates.

The various operations described herein (such as the operations—for example operation 2016—of the method 2000) can be conducted automatically using the controller 195, or can be conducted automatically or manually with certain operations conducted by a user.

In one or more embodiments, the controller 195 includes a mass storage device, an input control unit, and a display unit. The controller 195 monitors the temperature of the substrate 102, the temperature of the substrate support 106, the temperature of the upper window 108, the process gas flow, and/or the purge gas flow. In one or more embodiments, the controller 195 includes multiple controllers 195, such that the stored readings and calculations and the system model are stored within a separate controller from the controller 195 which controls the operations of the processing chamber 100. In one or more embodiments, all of the system model and the stored readings and calculations are saved within the controller 195.

The controller 195 is configured to control the sensor devices, the deposition, the cleaning, the rotational position, the heating, and gas flow through the processing chamber 100 by providing an output to the controls for the heat sources, the gas flow, and the motion assembly 121. The controls include controls for the sensor devices, the upper heat sources 141, the lower heat sources 143, the process gas source 151, the purge gas source 162, the motion assembly 121, and the exhaust pump 157.

The controller 195 is configured to adjust the output to the controls based on the sensor readings, the system model, and the stored readings and calculations. The controller 195 includes embedded software and a compensation algorithm to calibrate measurements. The controller 195 can include one or more machine learning algorithms and/or artificial intelligence algorithms that estimate optimized parameters for the deposition operations and/or the cleaning operations (such as for adjusting a deposition operation (e.g. the process recipe), halting the deposition operation, initiating a chamber downtime period, delaying a subsequent iteration of the deposition operation, initiating a cleaning operation, halting the cleaning operation, adjusting a heating power, and/or adjusting the cleaning operation). The optimized parameter can include, for example, a center-to-edge profile for the substrate 102 (which facilitates uniformity) with respect to temperature, gas flow rate, substrate position, and/or deposition thickness.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or the method 2000 relative to other aspects of the process chamber 100 and/or the method 2000. The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100 and/or the method 2000. For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method 2000. The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, a heating power applied to the heat sources 141, 143 and/or one or more sizes of one or more cross-sectional areas of one or more exhaust pathways of the gas exhaust frames 600A, 600B. The one or more machine learning algorithms and/or artificial intelligence algorithms can optimize, for example, a size and/or a gas conductance of at least one exhaust pathway (such as all of the exhaust pathways) of the gas exhaust frames 600A, 600B.

The one or more machine learning algorithms and/or artificial intelligence algorithms can optimize, for example, a center-to-edge gas concentration profile across a substrate 102 during deposition operations. The center-to-edge gas concentration profile can be pre-generated using simulation operations, and the one or more machine learning algorithms and/or artificial intelligence algorithms can use real-time collected data to adjust the center-to-edge gas concentration profile. The center-to-edge concentration profile is affected, for example, by the sizes of the exhaust pathways.

In one or more embodiments, the controller 195 automatically conducts one or more operations described herein without the use of one or more machine learning algorithms or artificial intelligence algorithms. In one or more embodiments, the controller 195 compares measurements (such as of gas flow rate(s)) and/or deposition thickness to data in a look-up table and/or a library to determine if adjustment(s) can be used to facilitate a center-to-edge profile. The controller 195 can stored measurements as data in the look-up table and/or the library.

FIG. 2 is a schematic top view of the processing chamber 100 shown in FIG. 1, according to one or more embodiments.

The processing chamber 100 includes a gas inject assembly 185. In one or more embodiments, a side gas inject assembly 189 can inject the one or more process gases P1 in a cross-flow manner, in addition to the primary flow of the one or more process gases P1.

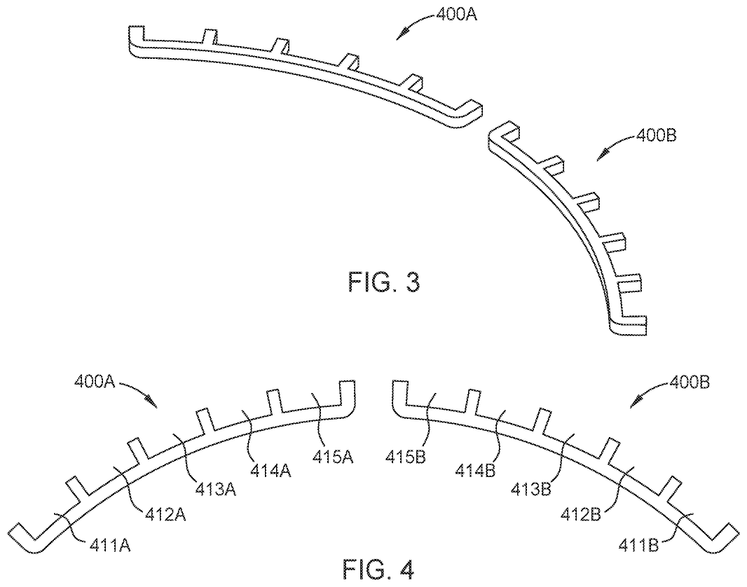

FIG. 3 is a schematic axonometric view of a pair of gas exhaust frames 400A, 400B, according to one or more embodiments.

FIG. 4 is a schematic top view of the pair of gas exhaust frames 400A, 400B shown in FIG. 3, according to one or more embodiments.

Each of the pair of gas exhaust frames 400A, 400B includes a plurality of exhaust pathways 411A-415A, 411B-415B. For each of the pair of gas exhaust frames 400A, 400B, the respective plurality of exhaust pathways 411A-415A, 411B-415B are substantially equal in size to each other.

FIG. 5 is a schematic axonometric view of a pair of gas exhaust frames 600A, 600B, according to one or more embodiments.

FIG. 6 is a schematic top view of the pair of gas exhaust frames 600A, 600B shown in FIG. 5, according to one or more embodiments.

Each gas exhaust frame 600A, 600B a first outer face 621A, 621B, a second outer face 622A, 622B, and a third outer face 623A, 623B. The second outer face 622A, 622B and the third outer face 623A, 623B extend relative to the first outer face 621A, 621B along a length L1. Each gas exhaust frame 600A, 600B has a height H1 between the second outer face 622A, 622B and the third outer face 623A, 623B. Each gas exhaust frame 600A, 600B has a width W1 that is larger than the length L1 and the height H1. Each of the pair of gas exhaust frames 600A, 600B includes a plurality of exhaust pathways 611A-615A, 611B-615B. For each of the pair of gas exhaust frames 600A, 600B, the respective plurality of exhaust pathways 611A-615A, 611B-615B have a size variation such that at least part of each exhaust pathway of the respective plurality of exhaust pathways 611A-615A, 611B-615B is different in size than each of the other exhaust pathways of the plurality of exhaust pathways 611A-615A, 611B-615B. In one or more embodiments, one or more of the exhaust pathways 611A-615A, 611B-615B are equal in size to each other. The first outer face 621A, 621B is arcuate. In one or more embodiments, the size variation is a size gradient. In one or more embodiments, the size gradient is a cross-sectional area gradient. In one or more embodiments, the cross-sectional area gradient is for the cross-sectional areas shown in FIG. 6 of the plurality of exhaust pathways 611A-615A, 611B-615B.

A first set of exhaust pathways 611A-615A are positioned on a first side of a reference plane RP1. A second set of exhaust pathways 611B-615B are positioned on a second side of the reference plane RP1, the second set of exhaust pathways having a second cross-sectional area gradient that increases along a second direction that is opposite of the first direction. When the first and second gas exhaust frames 600A, 600B are positioned in the opening 190 of the lower liner 109, the first set of exhaust pathways 611A-615A and the second set of exhaust pathways 611B-615B are positioned opposite of the one or more gas inlets 114 (shown in FIG. 1).

For a first gas exhaust frame 600A, the cross-sectional area gradient (e.g., a first cross-sectional area gradient for the first set of exhaust pathways 611A-615A) increases along a first direction D1 (e.g., an arcuate direction) parallel to the first outer face 621A of the first gas exhaust frame 600A. For a second gas exhaust frame 600B, the cross-sectional area gradient (e.g., a second cross-sectional area gradient for the second set of exhaust pathways 611B-615B) increases along a second direction D2 (e.g., an arcuate direction) parallel to the first outer face 621B of the second gas exhaust frame 600B. The second direction D2 is opposite of the first direction D1.

Each gas exhaust frame 600A, 600B includes an arcuate bar 625A, 625B and a plurality of legs 631A-636A, 631B-636B extending relative to the respective arcuate bar 625A, 625B. The respective plurality of legs 631A-636A, 631B-636B bound the respective plurality of exhaust pathways 611A-615A, 611B-615B. As shown in FIG. 1, the plurality of legs 631A-636A, 631B-636B abut against inner surface(s) of the upper liner 122 when positioned in the processing chamber 100, and the one or more process gases P1 flow vertically through the exhaust pathways 611A-615A, 611B-615B when exhausted from the process volume 136. The respective plurality of exhaust pathways 611A-615A, 611B-615B include a plurality of opening sections extending into the second outer face 622A, 622B, and extending from the second outer face 622A, 622B and to the third outer face 623A, 623B. The plurality of opening sections include the cross-sectional area gradient along the respective first direction D1 or second direction D2. The plurality of opening sections of the first set of exhaust pathways 611A-615A and the plurality of opening sections of the second set of exhaust pathways 611B-615B are aligned above the pre-heat ring 200 (as shown in FIG. 1).

A first end exhaust pathway 611A, 611B that is nearest to a first end 616A, 616B of the respective gas exhaust frame 600A, 600B has a first cross-sectional area (in the view shown in FIG. 6), and a second end exhaust pathway 615A, 615B that is nearest to a second end 617A, 617B of the respective gas exhaust frame 600A, 600B has a second cross-sectional area (in the view shown in FIG. 6) that is larger than the first cross-sectional area by a ratio of the first cross-sectional area. In one or more embodiments, the ratio is 0.2 or greater, such as within a range of 0.2 to 0.3. In one or more embodiments, the ratio is about 0.25. For each of the first gas exhaust frame 600A and the second gas exhaust frame 600B, the cross-sectional area gradient increases (respectively in the direction D1 and the direction D2) by a step S1 between the respective plurality of exhaust pathways 611A-615A, 6111B-615B. In one or more embodiments, the step S1 is within a range of 4.6% (0.046) to 6.8% (0.068). In one or more embodiments, the step S1 is within a range of 5.7% (0.057) to 5.8% (0.058), such as about 5.74% (0.0574).

The first end exhaust pathways 611A, 611B are respective outward exhaust pathways that are farthest from the reference plane RP1 for each set of exhaust pathways 611A-615A, 611B-615B. The second end exhaust pathways 615A, 615B are respective inward exhaust pathways that are nearest to the reference plane RP1 for each set of exhaust pathways 611A-615A, 611B-615B.

FIG. 7 is a schematic axonometric view of a pair of gas exhaust frames 800A, 800B, according to one or more embodiments.

FIG. 8 is a schematic top view of the pair of gas exhaust frames 800A, 800B shown in FIG. 7, according to one or more embodiments.

Each of the pair of gas exhaust frames 800A, 800B includes a plurality of exhaust pathways 811A-815A, 811B-815B. A first end exhaust pathway 811A, 811B that is nearest to the first end 616A, 616B of the respective gas exhaust frame 800A, 800B has a first cross-sectional area (in the view shown in FIG. 8), and a second end exhaust pathway 815A, 815B that is nearest to the second end 617A, 617B of the respective gas exhaust frame 800A, 800B has a second cross-sectional area (in the view shown in FIG. 8) that is larger than the first cross-sectional area by a second ratio of the first cross-sectional area. In one or more embodiments, the second ratio is 0.5 or greater, such as 0.7 or greater, for example 0.75 or greater. In one or more embodiments, the second ratio is within a range of 0.7 to 0.8, such as about 0.75. For each of the first gas exhaust frame 800A and the second gas exhaust frame 800B, the cross-sectional area gradient increases by a second step S2 between the respective plurality of exhaust pathways 811A-815A, 811B-815B. In one or more embodiments, the second step S2 is within a range of 10.5% (0.105) to 16% (0.16). In one or more embodiments, the second step S2 is within a range of 14% (0.14) to 16% (0.16), such as about 15% (0.15).

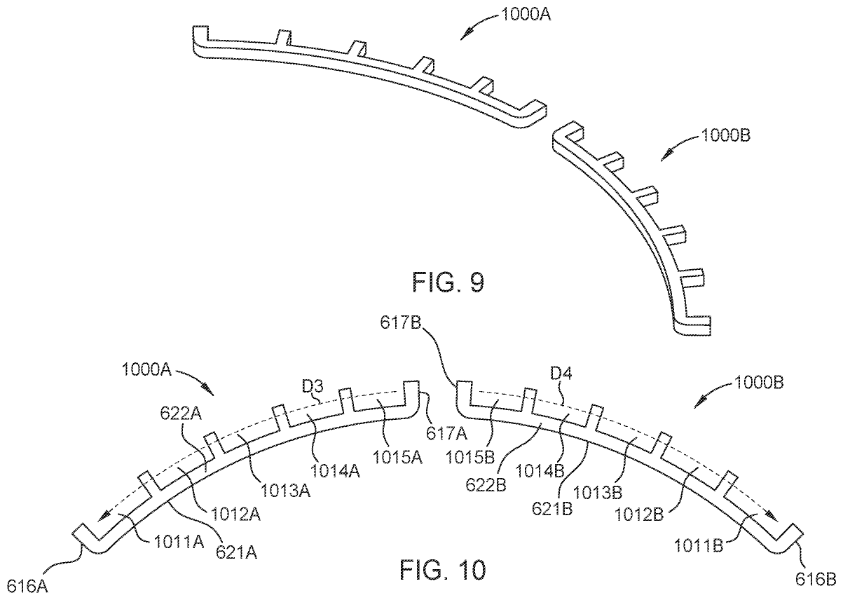

FIG. 9 is a schematic axonometric view of a pair of gas exhaust frames 1000A, 1000B, according to one or more embodiments.

FIG. 10 is a schematic top view of the pair of gas exhaust frames 1000A, 1000B shown in FIG. 9, according to one or more embodiments.

Each of the pair of gas exhaust frames 1000A, 1000B includes a plurality of exhaust pathways 1011A-1015A, 1011B-1015B. A first end exhaust pathway 1015A, 1015B that is nearest to the second end 617A, 617B of the respective gas exhaust frame 1000A, 1000B has a first cross-sectional area (in the view shown in FIG. 10), and a second end exhaust pathway 1011A, 1011B that is nearest to the first end 616A, 616B of the respective gas exhaust frame 1000A, 1000B has a second cross-sectional area (in the view shown in FIG. 10) that is larger than the first cross-sectional area by the ratio described above in relation to FIG. 6.

For a first gas exhaust frame 1000A, the cross-sectional area gradient increases along a first direction D3 (e.g., an arcuate direction) parallel to the first outer face 621A of the first gas exhaust frame 1000A. For a second gas exhaust frame 1000B, the cross-sectional area gradient increases along a second direction D4 (e.g., an arcuate direction) parallel to the first outer face 621B of the second gas exhaust frame 1000B. The second direction D4 is opposite of the first direction D3. For each of the first gas exhaust frame 1000A and the second gas exhaust frame 1000B, the cross-sectional area gradient increases (respectively in the first direction D3 and the second direction D4) by the step S1 (described above in relation to FIG. 6) between the respective plurality of exhaust pathways 1011A-1015A, 1011B-1015B.

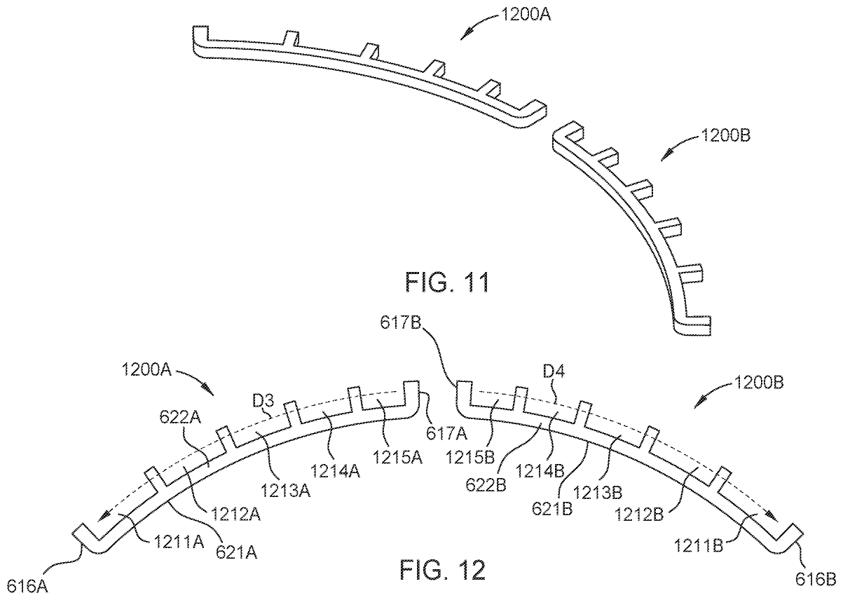

FIG. 11 is a schematic axonometric view of a pair of gas exhaust frames 1200A, 1200B, according to one or more embodiments.

FIG. 12 is a schematic top view of the pair of gas exhaust frames 1200A, 1200B shown in FIG. 11, according to one or more embodiments.

Each of the pair of gas exhaust frames 1200A, 1200B includes a plurality of exhaust pathways 1211A-1215A, 1211B-1215B. A first end exhaust pathway 1215A, 1215B that is nearest to the second end 617A, 617B of the respective gas exhaust frame 1200A, 1200B has a first cross-sectional area (in the view shown in FIG. 12), and a second end exhaust pathway 1211A, 1211B that is nearest to the first end 616A, 616B of the respective gas exhaust frame 1200A, 1200B has a second cross-sectional area (in the view shown in FIG. 12) that is larger than the first cross-sectional area by the second ratio described above in relation to FIG. 8.

For a first gas exhaust frame 1200A, the cross-sectional area gradient increases along the first direction D3 (e.g., an arcuate direction) parallel to the first outer face 621A of the first gas exhaust frame 1200A. For a second gas exhaust frame 1200B, the cross-sectional area gradient increases along the second direction D4 (e.g., an arcuate direction) parallel to the first outer face 621B of the second gas exhaust frame 1200B. For each of the first gas exhaust frame 1200A and the second gas exhaust frame 1200B, the cross-sectional area gradient increases (respectively in the first direction D3 and the second direction D4) by the second step S2 (described above in relation to FIG. 8) between the respective plurality of exhaust pathways 1211A-1215A, 1211B-1215B.

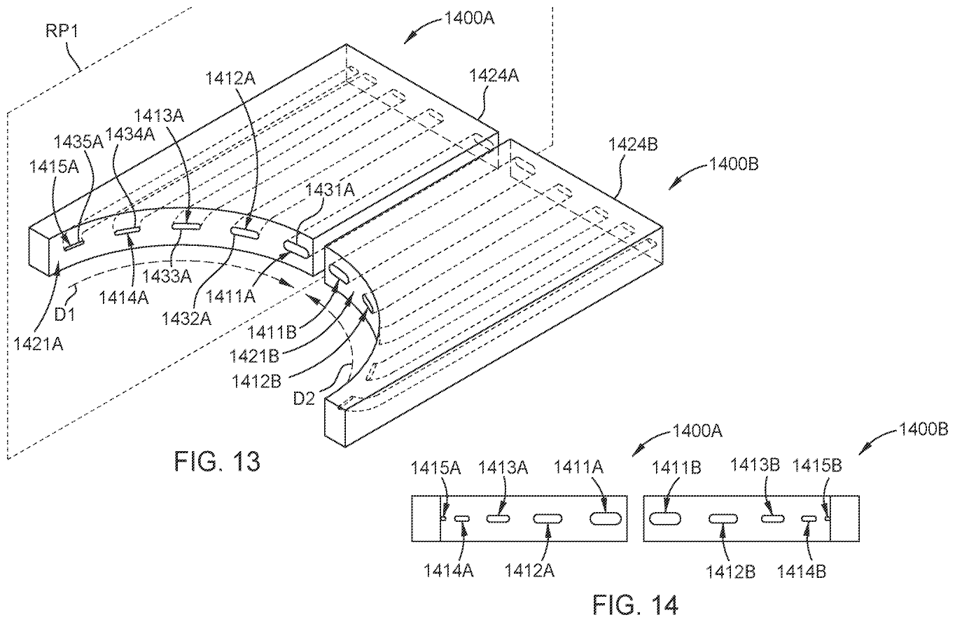

FIG. 13 is a schematic axonometric view of a pair of gas exhaust frames 1400A, 1400B, according to one or more embodiments. The gas exhaust frames 1400A, 1400B can be used at least partially in place of the gas exhaust frames 600A, 600B shown in FIGS. 1 and 5.

FIG. 14 is a schematic front view of the pair of gas exhaust frames 1400A, 1400B shown in FIG. 13, according to one or more embodiments.

A first gas exhaust frame 1400A includes a first set of exhaust pathways 1411A-1415A. The first set of exhaust pathways 1411A-1415A include a plurality of opening sections 1431A-1435A extending into a first outer face 1421A of the first gas exhaust frame 1400A, and from the first outer face 1421A and to a second outer face 1424A of the first gas exhaust frame 1400A. The plurality of opening sections 1431A-1435A of the first set include the first cross-sectional area gradient increasing in the first direction D1.

A second gas exhaust frame 1400B includes a second set of exhaust pathways 1411B-1415B. The second set of exhaust pathways 1411B-1415B include a plurality of opening sections 1431B-1435B extending into a first outer face 1421B of the second gas exhaust frame 1400B. The plurality of opening sections 1431B-1435B of the second set include the second cross-sectional area gradient increasing in the second direction D2.

In one or more embodiments (as shown in FIGS. 13 and 14), the first cross-sectional area gradient and/or the second cross-sectional area gradient include the ratio and/or the first step S1 (described in relation to FIG. 6). The present disclosure contemplates that the first cross-sectional area gradient and/or the second cross-sectional area gradient can include the second ratio and/or the second step S2 (described in relation to FIG. 8).

The gas exhaust frames 1400A, 1400B can be inserted through one or more sidewalls of the processing chamber 100, and can extend at least partially into the opening 190 of the lower liner 109.

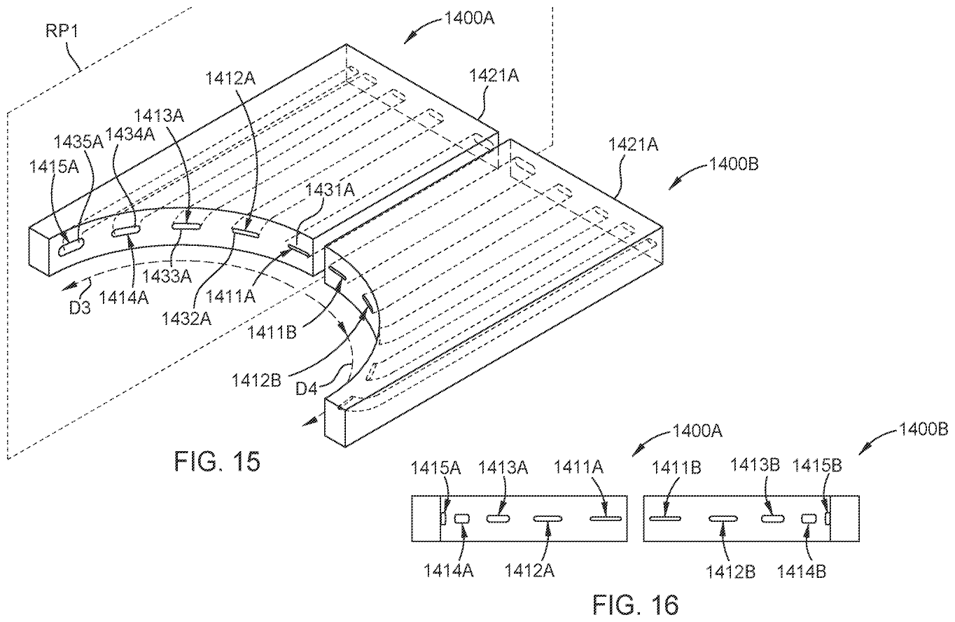

FIG. 15 is a schematic axonometric view of the pair of gas exhaust frames 1400A, 1400B shown in FIGS. 13 and 14, according to one or more embodiments. The gas exhaust frames 1400A, 1400B can be used at least partially in place of the gas exhaust frames 600A, 600B shown in FIGS. 1 and 5.

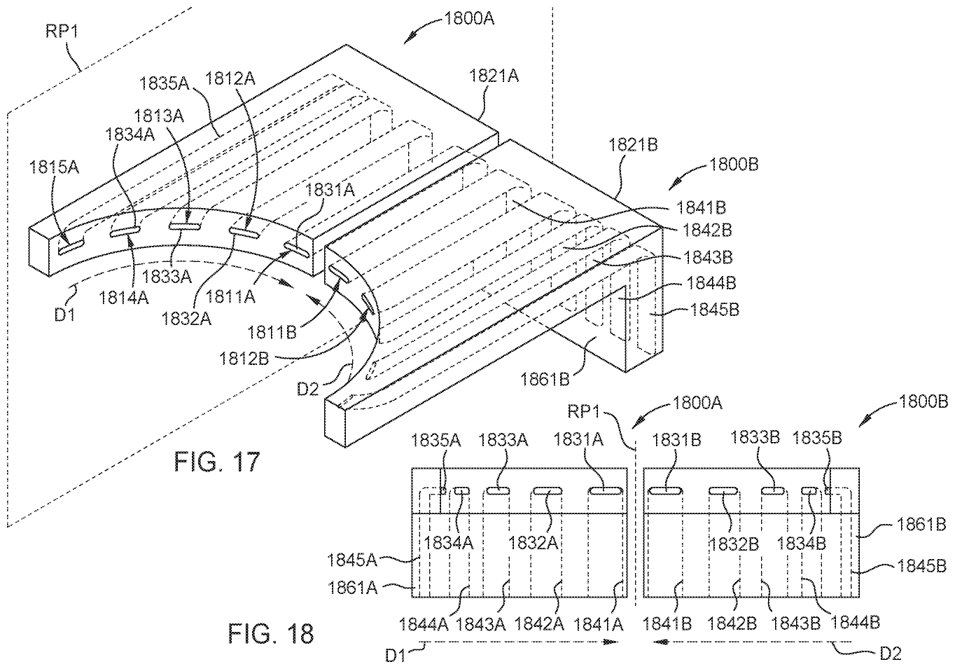

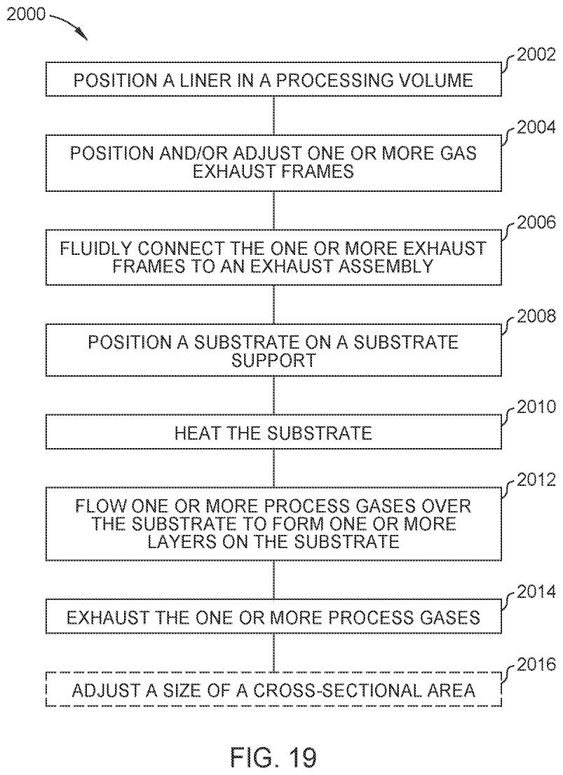

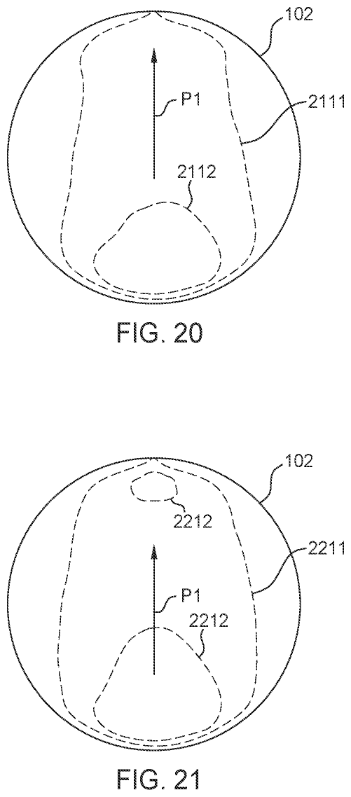

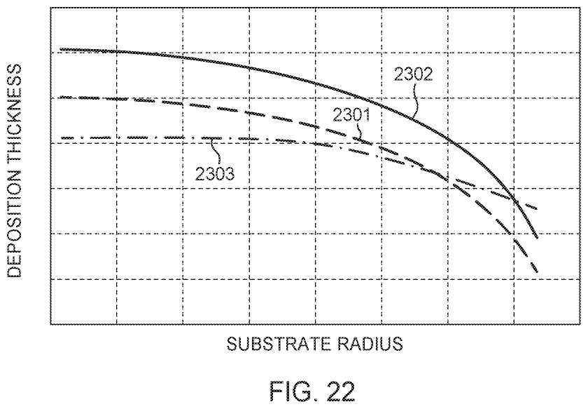

FIG. 16 is a schematic front view of the pair of gas exhaust frames 1400A, 1400B shown in FIG. 15, according to one or more embodiments.

In the implementation shown in FIGS. 15 and 16, the plurality of opening sections 1431A-1435A of the first set include the first cross-sectional area gradient increasing in the first direction D3, and the plurality of opening sections 1431B-1435B of the second set include the second cross-sectional area gradient increasing in the second direction D4.

FIG. 17 is a schematic axonometric view of a pair of gas exhaust frames 1800A, 1800B, according to one or more embodiments. The gas exhaust frames 1800A, 1800B can be used at least partially in place of the gas exhaust frames 600A, 600B shown in FIGS. 1 and 5.

FIG. 18 is a schematic front view of the pair of gas exhaust frames 1800A, 1800B shown in FIG. 17, according to one or more embodiments.

A first gas exhaust frame 1800A includes a first set of exhaust pathways 1811A-1815A. The first set of exhaust pathways 1811A-1815A include a plurality of first opening sections 1831A-1835A extending into the first outer face 1421A of the first gas exhaust frame 1800A, and a plurality of second opening sections 1841A-1845A intersecting the plurality of first opening sections 1831A-1835A at an angle. In one or more embodiments, the plurality of second opening sections 1841A-1845A include the first cross-sectional area gradient that increases in the first direction D1 (e.g., toward the reference plane RP1). The present disclosure contemplates that the first cross-sectional area gradient can increase in the first direction D3 (e.g., away from the reference plane RP1). A first opening section 1835A and a second opening section 1845A are shown in ghost for FIG. 17 for an end exhaust gas pathway 1815A of the first gas exhaust frame 1800A.

A second gas exhaust frame 1800B includes a second set of exhaust pathways 1811B-1815B. The second set of exhaust pathways 1811B-1815B include a plurality of first opening sections 1831B-1835B extending into the first outer face 1421B of the second gas exhaust frame 1800B. The plurality of first opening sections 1831B-1835B of the second set include the second cross-sectional area gradient increasing in the second direction D2 (e.g., toward the reference plane RP1). The present disclosure contemplates that the second cross-sectional area gradient can increase in the second direction D4 (e.g., away from the reference plane RP1).

In one or more embodiments (as shown in FIGS. 17 and 18), the first cross-sectional area gradient and/or the second cross-sectional area gradient include the ratio and/or the first step S1 (described in relation to FIG. 6). The present disclosure contemplates that the first cross-sectional area gradient and/or the second cross-sectional area gradient can include the second ratio and/or the second step S2 (described in relation to FIG. 8).

In one or more embodiments, for each of the pair of gas exhaust frames 1800A, 1800B, the respective plurality of first opening sections 1831A-1835A, 1831B-1835B are substantially equal in size (e.g., cross-sectional area size) to each other.

The plurality of first opening sections 1831A-1835A, 1831B-1835B and the plurality of second opening sections 1841A-1845A, 1841B-1845B are shown as elongated slots in FIGS. 17 and 18. The present disclosure contemplates that the plurality of first opening sections 1831A-1835A, 1831B-1835B and/or the plurality of second opening sections 1841A-1845A, 1841B-1845B can be circular in shape, ovular in shape, and/or rectangular in shape (as shown for the exhaust pathways 411A-415A, 411B-415B in FIGS. 3 and 4).

The present disclosure contemplates that gas exhaust frames discussed herein (such as the gas exhaust frames 1800A, 1800B) can be omitted, and the exhaust pathways discussed herein (such as the sets of exhaust pathways 1811A-1815A, 1811B-1815B) can be formed in one or more components (such as the lower liner 109) of the processing chamber 100.

The present disclosure contemplates that the gas exhaust frames discussed herein can replace at least part of the gas boxes 179 shown in FIG. 2. For example, ledge sections 1861A, 1861B of the gas exhaust frames 1800A, 1800B can at least partially replace vertical sections of the gas boxes 179 shown in FIG. 2.

The present disclosure contemplates that although five exhaust pathways are shown for each gas exhaust frame herein, a different number (e.g., more or less, such as two, three, four, six, or more) exhaust pathways can be used for each gas exhaust frame. The number may depend, for example, on process requirements and/or design constraints.

FIG. 19 is a schematic flow diagram of a method 2000 of altering a processing chamber applicable for use in semiconductor processing, according to one or more embodiments.

Operation 2002 includes positioning a liner in a processing volume. The liner includes an opening.

Operation 2004 includes positioning and/or adjusting one or more gas exhaust frames at least partially in the opening of the liner. The one or more gas exhaust frames include a first set of exhaust pathways positioned on a first side of a reference plane. The first set of exhaust pathways have a first cross-sectional area gradient that increases along a first direction. The one or more gas exhaust frames include a second set of exhaust pathways positioned on a second side of the reference plane. The second set of exhaust pathways have a second cross-sectional area gradient that increases along a second direction that is opposite of the first direction. In one or more embodiments, the positioning and/or adjusting of the one or more gas exhaust frames adjusts a conductance of gas flow through the liner. In one or more embodiments, the positioning and/or adjusting of the one or more gas exhaust frames adjusts one or more of a flow ratio, a pressure, a temperature, and/or a purge flow of gas(es) through the liner.

Operation 2006 includes fluidly connecting the one or more exhaust frames to an exhaust assembly. In one or more embodiments, the exhaust assembly includes a plurality of gas boxes and a common exhaust box that includes a common plenum.

Operation 2008 includes positioning a substrate on a substrate support in the processing volume.

Operation 2010 includes heating the substrate.

Operation 2012 includes flowing one or more process gases over the substrate. The process gasses form (e.g., epitaxially) one or more layers on the substrate.

Operation 2014 includes exhausting the one or more process gases from the chamber. The one or more process gases are exhausted through the first set of exhaust pathways and the second set of exhaust pathways of the one or more gas exhaust frames. The one or more gas exhaust frames are fluidly connected to an exhaust pump.

Optional operation 2016 includes adjusting a size of a cross-sectional area of one or more of: at least one exhaust passage of the first set of exhaust pathways or at least one exhaust passage of the second set of exhaust pathways. In one or more embodiments, the adjustment of the size is conducted in real-time and in an in-situ manner. For example, a block and/or a plate can be moved (e.g., actuator) in real time to adjust the size of the cross-sectional area. As an example, one or more of blocks 671-675 shown in ghost in FIG. 6 can be moved (e.g., outwardly along radial direction RD1) to block or open the respective exhaust pathway 611A-615A. The present disclosure contemplates that blocks similar to the blocks 671-675 can be included for the second set of exhaust pathways 611B-615B.

The method 2000 can be used to retrofit processing chambers. For example, an existing liner can be replaced with the liner referenced in operation 2002 to alter sizes of exhaust pathways of a processing chamber.

FIG. 20 is a schematic top view of a substrate 102 during a deposition operation, according to one or more embodiments.

FIG. 21 is a schematic top view of a substrate 102 during a deposition operation, according to one or more embodiments.

In FIG. 20, a first boundary 2111 bounds an area having a first gas flow concentration, and a second boundary 2112 bounds an area having a second gas flow concentration that is higher than the first gas flow concentration of the first boundary 2111.

In FIG. 21, a first boundary 2211 bounds an area having a first gas flow concentration, and a second boundary 2212 bounds two areas having a second gas flow concentration that is higher than the first gas flow concentration of the first boundary 2211. In FIG. 21, the first and second cross-sectional area gradients described above are used to exhaust the one or more process gases P1. As shown in FIG. 21, a plume shape (e.g., of the first boundary 2211) is reduced relative to FIG. 20 (e.g., of the first boundary 2111).

FIG. 22 is a schematic graphical view of deposition thickness versus substrate radius, according to one or more embodiments.

A first profile 2301 shows a deposition thickness profile across a surface of a first substrate, and a second profile 2302 shows a deposition thickness profile across a surface of a second substrate (using the first and second cross-sectional area gradients described above to exhaust the one or more process gases P1). As shown by the second profile 2302, the deposition thickness of film epitaxially deposited on the second substrate is higher from a center of the second substrate and to an outer edge of the second substrate.

A third profile 2303 shows a deposition thickness profile across a surface of a third substrate. As shown by the third profile 2303, gas flow over the third substrate is controlled and distributed such that a center-to-edge non-uniformity is reduced (relative to the first and second profiles 2301, 2302) by reducing thickness near a center of the third substrate and increasing thickness neat an outer edge of the third substrate. Benefits of the present disclosure includes adjustability of processing parameters (such as gas flow rates, processing temperatures, and/or deposition profiles-such as center-to-edge profiles); reduced gas flow non-uniformities; enhanced deposition thicknesses; increased throughput; enhanced center-to-edge deposition uniformities; modularity of adjusting processing parameters; quickly, simply, and cost-effectively adjusting exhaust pathway sizes to adjust processing parameters; and modularity in simply retrofitting a variety of processing chambers that conduct different operations (e.g., different processing operations). By using a variety of configurations for gas exhaust frames, a gas flow boundary shape can be a variety of shapes (e.g., inverted U-shaped, U-shaped, M-shaped, or W shaped) and can facilitate a variety of center-to-edge deposition thickness uniformity profiles.

The present disclosure describes apparatus, systems, and methods used in relation to epitaxial deposition chambers. The present disclosure contemplates that the apparatus, systems, and methods described herein can be used in relation to a variety of other chambers, such as other epitaxial chambers and/or chambers that conduct other processes.

It is contemplated that one or more aspects disclosed herein may be combined. As an example, one or more aspects, features, components, operations and/or properties of the processing chamber 100, the controller 195, the gas exhaust frames 400A, 400B, gas exhaust frames 600A, 600B, gas exhaust frames 800A, 800B, gas exhaust frames 1000A, 1000B, gas exhaust frames 1200A, 1200B, gas exhaust frames 1400A, 1400B, gas exhaust frames 1800A, 1800B, and/or the method 2000 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body;
a window, the chamber body and the window at least partially defining a processing volume;
one or more heat sources configured to heat the processing volume;
a substrate support disposed in the processing volume;
a liner at least partially lining the chamber body;
a pre-heat ring disposed in the processing volume and at least partially supported by the liner;
one or more gas inlets; and
a first set of exhaust pathways positioned opposite of the one or more gas inlets on a first side of a reference plane, the first set of exhaust pathways having a first cross-sectional area gradient that increases along a first direction; and
a second set of exhaust pathways positioned opposite of the one or more gas inlets on a second side of the reference plane, the second set of exhaust pathways having a second cross-sectional area gradient that increases along a second direction that is opposite of the first direction.

2. The processing chamber of claim 1, wherein an inward exhaust pathway of each of the first set and the second set that is nearest to the reference plane has a first cross-sectional area, and an outward exhaust pathway of each of the first set and the second set that is farthest from the reference plane has a second cross-sectional area that is larger than the first cross-sectional area by a ratio of the first cross-sectional area, wherein the ratio is 0.2 or greater.

3. The processing chamber of claim 1, wherein an outward exhaust pathway of each of the first set and the second set that is farthest from the reference plane has a first cross-sectional area, and an inward exhaust pathway of each of the first set and the second set that is closest to the reference plane has a second cross-sectional area that is larger than the first cross-sectional area by a ratio of the first cross-sectional area, wherein the ratio is 0.2 or greater.

4. The processing chamber of claim 1, further comprising:
a first gas exhaust frame having the first set of exhaust pathways, wherein the first set of exhaust pathways comprise a plurality of opening sections extending into an outer face of the first gas exhaust frame, wherein the plurality of opening sections of the first set include the first cross-sectional area gradient; and
a second gas exhaust frame having the second set of exhaust pathways, wherein the second set of exhaust pathways comprise a plurality of opening sections extending into an outer face of the second gas exhaust frame, wherein the plurality of opening sections of the second set include the second cross-sectional area gradient.

5. The processing chamber of claim 4, wherein the first gas exhaust frame and the second gas exhaust frame are positioned at least partially in an opening formed in the liner.

6. The processing chamber of claim 4, wherein the plurality of opening sections of the first set and the plurality of opening sections of the second set are aligned above the pre-heat ring.

7. A gas exhaust frame for insertion in a processing chamber applicable for use in semiconductor manufacturing, the gas exhaust frame comprising:
a first outer face;
a second outer face;
a third outer face, the second outer face and the third outer face extending relative to the first outer face along a length, the gas exhaust frame having a height between the second outer face and the third outer face; and
a plurality of exhaust pathways having a size variation such that at least part of each exhaust pathway of the plurality of exhaust pathways is different in size than each of the other exhaust pathways of the plurality of exhaust pathways.

8. The gas exhaust frame of claim 7, wherein the first outer face is arcuate.

9. The gas exhaust frame of claim 8, wherein the size variation is a size gradient.

10. The gas exhaust frame of claim 9, wherein the size gradient is a cross-sectional area gradient.

11. The gas exhaust frame of claim 10, wherein the cross-sectional area gradient increases along a direction parallel to the first outer face.

12. The gas exhaust frame of claim 11, wherein a first end exhaust pathway that is nearest to a first end of the gas exhaust frame has a first cross-sectional area, and a second end exhaust pathway that is nearest to a second end of the gas exhaust frame has a second cross-sectional area that is larger than the first cross-sectional area by a ratio of the first cross-sectional area, wherein the ratio is 0.2 or greater.

13. The gas exhaust frame of claim 11, comprising an arcuate bar and a plurality of legs extending relative to the arcuate bar, the plurality of legs bounding the plurality of exhaust pathways.

14. The gas exhaust frame of claim 11, wherein the cross-sectional area gradient increases by a step between the plurality of exhaust pathways, and the step is within a range of 4.6% to 6.8%.

15. The gas exhaust frame of claim 14, wherein the step is within a range of 5.7% to 5.8%.

16. The gas exhaust frame of claim 11, wherein the plurality of exhaust pathways comprise a plurality of first opening sections extending from the second outer face and to the third outer face, and the plurality of first opening sections include the cross-sectional area gradient.

17. The gas exhaust frame of claim 11, wherein the plurality of exhaust pathways comprise:
a plurality of first opening sections; and
a plurality of second opening sections intersecting the plurality of first opening sections at an angle, wherein the plurality of second opening sections include the cross-sectional area gradient.

18. A method of altering a processing chamber applicable for use in semiconductor processing, the method comprising:
positioning a liner in a processing volume, the liner comprising an opening;
positioning one or more gas exhaust frames at least partially in the opening of the liner, the one or more gas exhaust frames comprising:
a first set of exhaust pathways positioned on a first side of a reference plane, the first set of exhaust pathways having a first cross-sectional area gradient that increases along a first direction;
a second set of exhaust pathways positioned on a second side of the reference plane, the second set of exhaust pathways having a second cross-sectional area gradient that increases along a second direction that is opposite of the first direction; and
fluidly connecting the one or more gas exhaust frames to an exhaust assembly.

19. The method of claim 18, further comprising:
positioning a substrate on a substrate support in the processing volume;
flowing one or more process gases over the substrate to form one or more layers on the substrate; and
exhausting the one or more process gases through the first set of exhaust pathways and the second set of exhaust pathways.

20. The method of claim 19, further comprising:
adjusting a size of a cross-sectional area of one or more of: at least one exhaust passage of the first set of exhaust pathways or at least one exhaust passage of the second set of exhaust pathways.
